(19) United States
(12) Patent Application Publication
(10) Pub. No.: US 2021/0140035 A1
(43) Pub. Date: May 13, 2021

(54) Compound Motion Vacuum Environment Deposition Source Shutter Mechanism

(71) Applicant: Kurt J. Lesker Company, Jefferson Hills, PA (US)

(72) Inventors: David Manko, Jefferson Hills, PA (US); Daniel Edward Carlsen, Canonsburg, PA (US); Michael Paul Bendis, Uniontown, PA (US)

(21) Appl. No.: 17/087,749

(22) Filed: Nov. 3, 2020

Related U.S. Application Data
(60) Provisional application No. 62/932,546, filed on Nov. 8, 2019.

(51) Int. Cl. C23C 14/56; C23C 14/24

(52) U.S. Cl. CPC C23C 14/564; C23C 14/243

(57) ABSTRACT

A shutter mechanism for a deposition source includes: an actuator; a shutter operatively connected to the actuator; and a linkage arrangement that operatively connects the shutter to the actuator, where the linkage arrangement is configured to move the shutter in a compound motion relative to the actuator between an open position and a closed position.

### CROSS REFERENCE TO RELATED APPLICATIONS

This application claims the benefit of U.S. Provisional Patent Application No. 62/932,546, filed Nov. 8, 2019, the disclosure of which is hereby incorporated by reference in its entirety.

### BACKGROUND OF THE INVENTION

### Field of the Invention

The present disclosure is directed to a shutter mechanism for a deposition source, and more particularly, to a shutter mechanism for a deposition source with a compound motion having two or more axes of movement.

### Description of Related Art

Current shutter mechanisms known in the art utilize only a simple motion, which includes one of the following motions: linear motion, rotary swing motion, or rotary flip motion. These commonly used motions limit the amount of shielding and coverage provided by the shutter mechanism due to the required clearance for movement between the shutter and the deposition source, or require a large motion profile with respect to the size of the deposition source, resulting in a large footprint or potential interference with other aspects of the vacuum envelope (i.e., the system or chamber) or process.

When operating any single physical vapor deposition (PVD) source, material particles from that deposition source have the possibility to present themselves and to deposit onto any exposed surface within the vacuum envelope. With a plurality of deposition sources inside of any given vacuum envelope, such as a plurality of material and source combinations, the deposition from different material and source combinations can contaminate one another, thereby creating cross contamination within the vacuum envelope.

Additionally, deposition sources can also be exposed to potential contaminates by other means. For example, the deposition source may be exposed to contaminants through desorbed materials from heating a system or chamber, as in the case of bake-out, or particles released when cleaning a substrate via any in-situ method of ion cleaning.

### SUMMARY OF THE INVENTION

In view of the foregoing, there is a current need in the art for a shutter mechanism for a deposition source that provides a compound motion to improve the performance and the footprint of the deposition source. There is a current need in the art for a more complete shielding and coverage of the deposition source and its material with improved shuttering to maintain the material's purity and allow for higher quality films deposited onto the substrate(s).

In one aspect of the present disclosure, a shutter mechanism for a deposition source includes: an actuator; a shutter operatively connected to the actuator; and a linkage arrangement that operatively connects the shutter to the actuator, wherein the linkage arrangement is configured to move the shutter in a compound motion relative to the actuator between an open position and a closed position.

The compound motion may include a linear movement of the shutter and a rotational movement of the shutter relative to the actuator. The rotational movement may move the shutter between the open position and an intermediate position. The linear movement may move the shutter between the intermediate position and the closed position. The actuator may be a mechanical actuator. The shutter, when in the open position, may be located at an angle in the range of 40° to 90° relative to a positive y-axis that extends through the actuator. The shutter, when in the closed position, may enclose at least one end of the deposition source. The linkage arrangement may include at least one pin-in-slot joint that guides the shutter through the compound motion. The compound motion may include only two types of movement for the shutter. The shutter may include an overhang on an outermost rim of the shutter that is positioned around a source material when the shutter is held in the closed position. The deposition source may be selected from the group consisting of a sputtering source, a low temperature evaporation source, an electron beam evaporation source, and a thermal evaporation source.

In another aspect of the present disclosure, a shutter mechanism arrangement includes: a plurality of deposition sources; and a plurality of shutter mechanisms, wherein a single shutter mechanism is operatively connected to a single deposition source, wherein each shutter mechanism includes: an actuator; a shutter operatively connected to the actuator; and a linkage arrangement that operatively connects the shutter to the actuator, wherein the linkage arrangement is configured to move the shutter in a compound motion relative to the actuator between an open position and a closed position.

The compound motion may include a linear movement of the shutter and a rotational movement of the shutter relative to the actuator. The rotational movement may move the shutter between the open position and an intermediate position. The linear movement may move the shutter between the intermediate position and the closed position. The actuator may be a mechanical actuator. The shutter, when in the open position, may be located at an angle in the range of 40° to 90° relative to a positive y-axis that extends through the actuator. The shutter, when in the closed position, may enclose at least one end of the deposition source. The linkage arrangement may include at least one pin-in-slot joint that guides the shutter through the compound motion. The compound motion may include only two types of movement for the shutter. The shutter may include an overhang on an outermost rim of the shutter that is positioned around a source material when the shutter is held in the closed position. The plurality of deposition sources may be selected from the group consisting of a sputtering source, a low temperature evaporation source, an electron beam evaporation source, and a thermal evaporation source.

In another aspect of the present disclosure, a method of enclosing a deposition source with a shutter mechanism, including the steps of: actuating an actuator; rotationally moving a shutter from an open position to an intermediate position; and linearly moving the shutter from the intermediate position to a closed position in which the shutter encloses at least one end of the deposition source.

The rotationally moving step may include rotationally moving the shutter from an angle in the range of 40° to 90° relative to a positive y-axis of the actuator to an angle of about 0° relative to the positive y-axis.

Various preferred and non-limiting examples or aspects of the present invention will now be described and set forth in the following numbered clauses:

Clause 1: A shutter mechanism for a deposition source, including: an actuator; a shutter operatively connected to the actuator; and a linkage arrangement that operatively connects the shutter to the actuator, where the linkage arrangement is configured to move the shutter in a compound motion relative to the actuator between an open position and a closed position.

Clause 2: The shutter mechanism of clause 1, wherein the compound motion comprises a linear movement of the shutter and a rotational movement of the shutter relative to the actuator, wherein the rotational movement moves the shutter between the open position and an intermediate position, and wherein the linear movement moves the shutter between the intermediate position and the closed position.

Clause 3: The shutter mechanism of clause 1 or 2, where the actuator is a mechanical actuator.

Clause 4: The shutter mechanism of any one of clauses 1-3, where, when in the open position, the shutter is located at an angle in the range of 40° to 90° relative to a positive y-axis that extends through the actuator.

Clause 5: The shutter mechanism of any one of clauses 1-4, where, when in the closed position, the shutter encloses at least one end of the deposition source.

Clause 6: The shutter mechanism of any one of clauses 1-5, where the linkage arrangement includes at least one pin-in-slot joint that guides the shutter through the compound motion.

Clause 7: The shutter mechanism of any one of clauses 1-6, where the compound motion includes only two types of movement for the shutter.

Clause 8: The shutter mechanism of any one of clauses 1-7, where the shutter includes an overhang on an outermost rim of the shutter that is positioned around a source material when the shutter is held in the closed position.

Clause 9: The shutter mechanism of any one of clauses 1-8, where the deposition source is selected from the group consisting of a sputtering source, a low temperature evaporation source, an electron beam evaporation source, and a thermal evaporation source.

Clause 10: The shutter mechanism of any one of clauses 1-9, where the actuator further includes a pneumatic supply tube.

Clause 11: The shutter mechanism of any one of clauses 1-10, where the deposition source is secured to the shutter mechanism with a mounting arrangement.

Clause 12: A shutter mechanism arrangement, including: a plurality of deposition sources; and a plurality of shutter mechanisms, where a single shutter mechanism is operatively connected to a single deposition source, where each shutter mechanism includes: an actuator; a shutter operatively connected to the actuator; and a linkage arrangement that operatively connects the shutter to the actuator, where the linkage arrangement is configured to move the shutter in a compound motion relative to the actuator between an open position and a closed position.

Clause 13: The shutter mechanism arrangement of clause 12, where the compound motion includes a linear movement of the shutter and a rotational movement of the shutter relative to the actuator, where the rotational movement moves the shutter between the open position and an intermediate position, where the linear movement moves the shutter between the intermediate position and the closed position.

Clause 14: The shutter mechanism arrangement of clause 12 or 13, where the actuator is a mechanical actuator.

Clause 15: The shutter mechanism arrangement of any one of clauses 12-14, where, when in the open position, the shutter is located at an angle in the range of 40° to 90° relative to a positive y-axis that extends through the actuator.

Clause 16: The shutter mechanism arrangement of any one of clauses 12-15, where, when in the closed position, the shutter encloses at least one end of the deposition source.

Clause 17: The shutter mechanism arrangement of any one of clauses 12-16, where the linkage arrangement includes at least one pin-in-slot joint that guides the shutter through the compound motion.

Clause 18: The shutter mechanism arrangement of any one of clauses 12-17, where the compound motion includes only two types of movement for the shutter.

Clause 19: The shutter mechanism arrangement of any one of clauses 12-18, where the shutter includes an overhang on an outermost rim of the shutter that is positioned around a source material when the shutter is held in the closed position.

Clause 20: The shutter mechanism arrangement of any one of clauses 12-19, where the plurality of deposition sources are selected from the group consisting of a sputtering source, a low temperature evaporation source, an electron beam evaporation source, and a thermal evaporation source.

Clause 21: The shutter mechanism arrangement of any one of clauses 12-20, where the actuator further comprises a pneumatic supply tube.

Clause 22: The shutter mechanism arrangement of any one of clauses 12-21, where the plurality of deposition sources are secured to the plurality of shutter mechanisms with a mounting arrangement.

Clause 23: A method of enclosing a deposition source with a shutter mechanism, including the steps of: actuating an actuator; rotationally moving a shutter from an open position to an intermediate position; and linearly moving the shutter from the intermediate position to a closed position in which the shutter encloses at least one end of the deposition source.

Clause 24: The method of clause 23, where the rotationally moving step comprises rotationally moving the shutter from an angle in the range of 40° to 90° relative to a positive y-axis of the actuator to an angle of about 0° relative to the positive y-axis.

### BRIEF DESCRIPTION OF THE DRAWINGS

FIG. 1A is a left-side perspective view of a shutter mechanism according to one aspect of the present disclosure;

FIG. 1B is a right-side perspective view of a shutter mechanism according to another aspect of the present disclosure;

FIG. 1C is a right-side exploded view of a shutter mechanism according to another aspect of the present disclosure;

FIG. 1D is a left-side exploded view of a shutter mechanism according to another aspect of the present disclosure;

FIG. 2 is a left-side perspective view of a shutter mechanism with a deposition source according to another aspect of the present disclosure;

FIG. 3A is a rear view of a shutter mechanism with a deposition source according to another aspect of the present disclosure;

FIG. 3B is a left-side perspective view of a shutter mechanism with deposition source according to another aspect of the present disclosure;

FIG. 3C is a right-side perspective view of a shutter mechanism with deposition source according to another aspect of the present disclosure;

FIG. 4A is a rear view of a shutter mechanism with a deposition source, where the shutter is in a first position, according to another aspect of the present disclosure;

FIG. 4B is a left-side perspective view of a shutter mechanism with deposition source, where the shutter is in a first position, according to another aspect of the present disclosure;

FIG. 4C is a left-side perspective view of a shutter mechanism with deposition source, where the shutter is in a first position, according to another aspect of the present disclosure;

FIG. 4D is a rear view of a shutter mechanism with a deposition source, where the shutter is transitioning to a second position, according to another aspect of the present disclosure;

FIG. 4E is a right-side perspective view of a shutter mechanism with a deposition source, where the shutter is transitioning to a second position, according to another aspect of the present disclosure;

FIG. 4F is a left-side perspective view of a shutter mechanism with a deposition source, where the shutter is transitioning to a second position, according to another aspect of the present disclosure;

FIG. 4G is a rear view of a shutter mechanism with a deposition source, where the shutter is in a second position, according to another aspect of the present disclosure;

FIG. 4H is a rear view of a shutter mechanism with a deposition source, where the shutter is in a third position, according to another aspect of the present disclosure;

FIG. 5A is a right-side perspective view of a shutter mechanism with a deposition source according to another aspect of the present disclosure;

FIG. 5B is a left-side perspective view of a shutter mechanism with a deposition source according to another aspect of the present disclosure;

FIG. 6A is a left-side perspective view of a shutter mechanism with a deposition source according to another aspect of the present disclosure;

FIG. 6B is a right-side perspective view of a shutter mechanism with a deposition source according to another aspect of the present disclosure;

FIG. 7A is a perspective view of a plurality of shutter mechanisms, each with a deposition source and each shutter in a first position, according to another aspect of the present disclosure;

FIG. 7B is a perspective view of a plurality of shutter mechanisms, each with a deposition source and each shutter in a third position, according to another aspect of the present disclosure; and

FIG. 8 is a perspective view of a shutter mechanism with a deposition source according to another aspect of the present disclosure.

### DESCRIPTION OF THE INVENTION

For purposes of the description hereinafter, spatial orientation terms, as used, shall relate to the referenced embodiment as it is oriented in the accompanying drawings, figures, or otherwise described in the following detailed description. However, it is to be understood that the embodiments described hereinafter may assume many alternative variations and configurations. It is also to be understood that the specific components, devices, features, and operational sequences illustrated in the accompanying drawings, figures, or otherwise described herein are simply exemplary and should not be considered as limiting.

For purposes of the description hereinafter, the terms “upper,” “lower,” “right,” “left,” “vertical,” “horizontal,” “top,” “bottom,” “lateral,” “longitudinal,” and derivatives thereof shall relate to the invention as it is oriented in the drawing figures. However, it is to be understood that the invention may assume alternative variations and step sequences, except where expressly specified to the contrary. It is also to be understood that the specific devices and processes illustrated in the attached drawings, and described in the following specification, are simply exemplary embodiments of the invention. Hence, specific dimensions and other physical characteristics related to the embodiments disclosed herein are not to be considered as limiting.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

In this application, the use of the singular includes the plural and plural encompasses singular, unless specifically stated otherwise. In addition, in this application, the use of “or” means “and/or” unless specifically stated otherwise, even though “and/or” may be explicitly used in certain instances. Further, in this application, the use of “a” or “an” means “at least one” unless specifically stated otherwise.

The present disclosure is directed to, in general, a shutter mechanism for a deposition source, and in particular, to a shutter mechanism with a compound motion. Non-limiting examples of the components of the shutter mechanism are illustrated in FIGS. 1A-8.

According to one aspect, the shutter mechanism for a deposition source may move in a compound motion by utilizing an actuator with the purpose of isolating the deposition source, when inactive, from the deposition of other active sources in the same vacuum chamber, thereby significantly reducing or completely eliminating cross contamination. In one aspect of the present disclosure, a compound motion may be understood to mean motion with two or more axes of movement. The compound motion encloses the deposition source, such that the line-of-sight to other components (e.g., other deposition sources, substrates, and any resputtered material from other vacuum envelope components) is blocked. Due to an overhang of the shutter, material from other sources or resputtered material would find it difficult to reach the shielded source material, having to take a convoluted path to the shutter to reach the source material. Although only certain Figures of the present disclosure show the compound motion of the shutter mechanisms herein, it is respectfully noted that every shutter mechanism 2 described herein performs the compound motion.

With reference to FIGS. 1A-1D, according to one example of the present disclosure, a vacuum environment deposition shutter mechanism 2 (also referred to as “shutter mechanism 2”) is shown and described. The shutter mechanism 2 may provide a guided motion through pin-in-slot joint(s) 16 as well as an intermediate linkage 12 located between a driving single-axis actuator 10, motion guide(s) 14, and output linkage 18. The actuator 10 drives the motion of a shutter 20 of the shutter mechanism 2 and is connected to the rest of the shutter mechanism 2 via the intermediate linkage 12. The actuator 10 may be a mechanical actuator. In one example of the present disclosure, the actuator 10 may include a pneumatic supply tube 24 that supplies compressed air to actuate the actuator 10, thereby cycling the shutter 20 through a compound motion. The shutter 20 is provided to enclose a source material to prevent the exposure of the source material to any contaminates in the atmosphere. The shutter 20 may have an overhang 8. The overhang 8 may be defined as the bottom part of the shutter 20 having a larger circumference compared to a source material such that the shutter 20, and specifically the overhang 8, may fully enclose the source material in order to prevent contamination.

The arrangement of the pin-in-slot joint(s) 16 results in the shutter 20 being configured to cycle through the compound motion from an open position to a closed position. The pin-in-slot joint(s) 16 may be provided on the motion guide(s) 14, which is responsible for providing the surfaces and slots (i.e., the pin-in-slot joint(s) 16) that guide the motion of the shutter 20. The output linkage 18 may connect the shutter 20 to various other components of the shutter mechanism 2, such as the intermediate linkage 12 and indirectly to the actuator 10, and to the motion guide(s) 14 and pin-in-slot joint(s) 16. The shutter mechanism 2 may including mounting(s) 22 which may be a surface that various components of the shutter mechanism 2 may be mounted to, such as the motion guide(s) 16. The mounting(s) 22 may also allow for the shutter mechanism 2 to be mounted to another object, such as an apparatus for physical vapor deposition (PVD) (i.e., a PVD reactor).

The specifics of the compound motion of the shutter 20 are described below in connection with FIGS. 4A-4H, but it is noted that all of the shutters 20 of the shutter mechanisms 2 herein possess the ability to cycle through the described compound motion.

With reference to FIG. 2, a shutter mechanism 2 is provided with a deposition source 4. The shutter mechanism 2 may be substantially similar to, or the same as, the shutter mechanism 2 of FIGS. 1A-1D. The shutter mechanism 2 may be configured to cycle through a compound motion, from an open position to a closed position, in order to enclose a deposition source 4 from exposure to contaminants. The overhang 8 may be positioned such that it fully encloses the source material and rests upon the deposition source 4. In FIG. 2, the source material is provided under the shutter 20 and the overhang 8, such that it cannot be seen in FIG. 2. The deposition source 4 may be a sputtering deposition source for a PVD reactor. When using a sputtering source 4, a sputtering gas may be applied to the source material of the sputter source 4 such that ions of the source material are ejected from the source material. This ejected material may then be deposited on a surface of a substrate within the PVD reactor. When the shutter 20 is closed, such that the source material is enclosed by the shutter 20, any contaminants present are prevented from reaching the source material of the deposition source 4, such that none of the source material is ejected nor is the source material contaminated.

With reference to FIGS. 3A-3C, a shutter mechanism 2 with a deposition source 4 is shown and described. The shutter mechanism 2 may be the same as the shutter mechanism 2 shown and described with respect to FIGS. 1A-1D. The shutter mechanism 2 may be configured to cycle through a compound motion, from an open position to a closed position, in order to enclose a deposition source 4 from exposure to contaminants. The overhang 8 may be positioned such that it fully encloses the source material and rests upon the deposition source 4. In FIGS. 3A-3C, the source material of the deposition source 4 is provided under the shutter 20 and the overhang 8, such that it cannot be seen in FIG. 2. The deposition source 4 may be a sputter deposition source 4 for a PVD reactor, such as the sputter source shown in FIG. 2. The shutter mechanism 2 and the deposition (sputter) source 4 may be supported by a mounting tube 30. Between the mounting tube 30 and the shutter mechanism 2 and deposition source 4 may be a pivot joint 28 and bellows 26. The pivot joint 28 may be provided to allow the shutter mechanism 2 and deposition source 4 to pivot along an axis. Bellow(s) 26 may be provided to allow the expansion and flexibility of the shutter mechanism 2 and deposition source 4 when pivoting.

With reference to FIGS. 4A-4C, a shutter mechanism 2 with a deposition source 4 is provided. The shutter mechanism 2 may be the same as the shutter mechanism 2 shown and described with respect to FIGS. 1A-1D. The shutter mechanism 2 may be configured to cycle through a compound motion, from an open position to a closed position, in order to enclose a deposition source 4 from exposure to contaminants. The compound motion may include two movements, such as two different movements. For example, the compound motion may include two movements only. Specifically, with respect to FIGS. 4A-4C, the shutter mechanism 2 is provided in a first position 50. The first position 50 is an open position, where the shutter 20 does not cover the deposition source 4, but instead, is located away from the deposition source 4, such as to the side of the deposition source 4. When the shutter mechanism 2 is in the first position 50, the shutter 20 may be located at an angle of greater than 0° from the deposition source 4 relative to the positive y-axis. For example, the angle between the shutter 20 and the vertical y-axis may be greater than 0°, such as greater than 45°, such as about 90° relative to the positive y-axis. For example, in the first (open) position 50, the shutter 20 may be located at an angle in the range of greater than 0° to 180°, such as greater than 0° to 120°, such as 1° to 90°, such as 45° to 90°, relative to the positive y-axis.

The deposition source 4 may be a sputter deposition source 4 for a PVD reactor, such as the sputter source shown in FIG. 2. The shutter mechanism 2 and the deposition (sputter) source 4 may be supported by a mounting tube 30. Between the mounting tube 28 and the shutter mechanism 2 and deposition source 4 may be a pivot joint 28 and bellows 26. The pivot joint 28 may be provided to allow the shutter mechanism 2 and deposition source 4 to pivot along an axis. Bellow(s) 26 may be provided such as to allow the expansion and flexibility of the shutter mechanism 2 and deposition source 4 when pivoting. An air tube fitting 32 may be provided on the mounting tube 30 to allow for air to be supplied to the actuator 10.

With reference to FIG. 4G, the shutter mechanism with the deposition (sputtering) source 4 of FIGS. 4A-4C is provided with the shutter mechanism 2 in a second position 52 (also referred to as an intermediate position). Upon actuating the actuator 10 to close the shutter 20 from the first (open) position 50, the guide(s) 16 restrict the movement of the shutter 20 to a first motion, such as a rotary flip motion, during a first stage of movement. To close the shutter mechanism 2 in order to isolate the deposition source 4, the actuator 10 is actuated, such as using the pneumatic supply tube 24, causing, for example, a rotary flip motion in the shutter 20 and output linkage 18. The rotary flip motion of the shutter 20 moves the shutter 20 from the first (open) position 50 to a second (intermediate) position 52. FIGS. 4D-4F show the shutter 20 in the middle of performing the rotary flip motion, where the shutter 20 is transitioning from a first position 50 to a second position 52. Once the rotary flip motion is finished, the shutter 20 will be in the second position 52. The rotary flip motion may move the shutter 20 such that the shutter 20 is directed above the deposition source 4, but only partially covers and does not fully enclose the deposition source 4 (see FIG. 4G). For example, the rotary flip motion may move the shutter 20 such that the shutter 20 forms an approximately 0° angle with the positive y-axis. When the shutter 20 finishes its movement and is located directly above the deposition source 4, but not enclosing said source 4, it may be said that the shutter mechanism 2 is in a second (transitional) position 52. During the movement of the shutter 20, the shutter 20 will be guided by, for example, the output linkage 18 of which the shutter 20 is connected to. Through the compound motion, a pin on the output linkage 18 is guided through a pin-in-slot joint(s) 16 on at least the motion guide(s) 14. The path of the pin-in-slot joint(s) 16 that the pin on the output linkage 18 follows results in the rotary flip motion and/or linear stroke motion that is observed in the movement of the shutter 20 because the shutter 20 is attached to the output linkage 18.

With reference to FIG. 4H, the shutter mechanism 2 with the deposition (sputtering) source 4 of FIGS. 4A-4G is provided with the shutter mechanism 2 in a third position 54 (also referred to as a closed position). During a second stage of motion, the guide(s) 16 may restrict the shutter 20 to a second motion, such as a linear stroke motion, during a second stage of movement. With reference to FIG. 4H, the actuator 10, which has already been actuated with or without the pneumatic supply tube 24, causes the shutter 20 to finish its movement, for example, with a linear stroke motion that fully enclose the deposition source 4. The linear stroke motion of the shutter 20 moves the shutter 20 from the second (intermediate) position 52 to a third (closed) position 54. The linear stroke motion moves the shutter 20, which is located above the deposition source 4, in a vertical direction along the y-axis directly towards the deposition source 4. The linear stroke motion allows the shutter 20 to fully enclose the source material 6 of the deposition source 4, with the overhang 8 of the shutter 20 allowing for the full encapsulation around the source material 6 of the deposition source 4. Once the shutter 20 encloses the source material 6 (shown in FIG. 4H) of the deposition source 4, such as when the overhang 8 encloses the outermost edges of the source material 6 of the deposition source 4, the shutter mechanism 2 is said to be in a third (closed) position 54. Due to the overhang 8 of the shutter 20, material from other sources or resputtered material would find it difficult or impossible to reach the shielded source material 6, having to take a convoluted path around the shutter 20 to reach the source material 6.

With reference to the compound motion of the shutter mechanism 2 as discussed above in relation to the description of FIGS. 4A-4H, upon actuating the shutter mechanism 2 to open the shutter 20 (i.e., when the shutter 20 is in the third (closed) position), the shutter 20 will follow the previous closing steps, but in reverse order, so as to open the shutter 20. For example, in order to open the shutter 20, the actuator 10 is actuated with or without the pneumatic supply tube 24, causing the shutter 20 to move, for example, in a linear stroke motion away from the deposition source 4, such that the deposition source 4 is no longer enclosed. This linear stroke motion will transition the shutter 20 from the third (closed) position 54 back to the second (intermediate) position 52, shown in FIG. 4G. Once the linear stroke motion to the intermediate position 52 is completed, the shutter 20 may be located directly above the deposition source 4; however, the shutter 20 will no longer enclose the deposition source 4. Then, the shutter 20 may move, for example, in a rotary flip motion back to the fully open position 50 of FIGS. 4A-4C. During the reversal of the rotary flip motion, the shutter 20 may move from directly above of the deposition source 4 (i.e., at a 0° angle from the positive y-axis) to the side of the deposition source 4 (i.e., at an angle of about 90° from the positive y-axis). Upon completion of the rotary flip motion of the shutter 20, such as to a position of approximately 90° from the positive y-axis, the shutter 20 will be back into the first (open) position 50.

The compound motion of the shutter 20 facilitates enclosing the deposition source 4 such that line-of-sight to other components (e.g., sources, substrates, and any resputtered material from other vacuum envelope components) is blocked. Furthermore, in a vacuum envelope, the available physical space to perform shuttering (e.g., actuation and motion profile clearances) and to position shutter components is often restricted. The compound nature of this motion enables the shutter 20 to be located in a minimized or unobtrusive manner. The material contained within the deposition (PVD) source 4 is protected from other active sources, thereby significantly reducing or completely eliminating cross contamination. In the case of magnetron sputtering devices, this also provides the further benefit of pre-sputtering that does not disturb other source materials. It is respectfully noted that the compound motion described with respect to the shutter mechanism 2 of FIGS. 4A-4H is also provided for any other embodiments of the shutter mechanism 2 included herein. Any and/or all of the shutter mechanisms 2 described herein may possess the ability to cycle through the compound motion of a rotary flip motion and a linear stroke motion, thereby transitioning any and/or all of the shutter mechanisms 2 herein from a first position 50 to a second position 52, and then from a second position 52 to a third position 54.

With reference to FIGS. 5A-5B, a shutter mechanism 2 with a deposition source 34 is provided. The shutter mechanism 2 may be similar to the shutter mechanism 2 of FIGS. 1A-1D, including all the same components and optionally having a smaller size, such as a smaller shutter 20. For example, the shutter mechanism 2 may be the same as the shutter mechanism 2 of FIGS. 1A-1D. The shutter mechanism 2 includes the ability to move from a first (open) position 50 to a third (closed) position 54 using the compound motion detailed herein. The deposition source 34 may be a low temperature evaporation source 34. A low temperature evaporation source 34 is used in a PVD method that separates the source material from a heating element to allow for a precise control of the heating of the source material. The precise control over the heating of the source material allows for a fine control over the deposition rate of the source material onto a substrate. The shutter mechanism 2 and the low temperature evaporation source 34 may be mounted on lower mounting 36, which secures both the shutter mechanism 2 and the low temperature evaporation source 34 in place and also allows for the shutter mechanism 2 and low temperature evaporation source 34 to be mounted to another apparatus.

With reference to FIGS. 6A-6B, a shutter mechanism 2 with a deposition source 38 is provided. The shutter mechanism 2 may be similar to the shutter mechanism 2 FIGS. 1A-1D, including all the same components and optionally a smaller or larger size of one or more components. For example, the shutter mechanism 2 may be the same as the shutter mechanism of FIGS. 1A-1D. The shutter mechanism 2 includes the ability to move from a first (open) position 50 to a third (closed) position 54 using the compound motion detailed herein. The deposition source 38 may be an electron beam evaporation source 38. An electron beam evaporation source 38 is used in a PVD method that uses an electron beam that is generated from a filament and steered using electrical and magnetic fields to strike the source material, thereby vaporizing the source material allowing the vaporized material to be deposited onto a substrate. The shutter mechanism 2 and the electron beam evaporation source 38 may be mounted on lower mounting 36, which secures both the shutter mechanism 2 and the electron beam evaporation source 38 together and also allows the shutter mechanism 2 and the electron beam evaporation source 38 to be mounted to another apparatus.

With reference to FIGS. 7A-7B, a plurality of shutter mechanisms 2, each with their own deposition source 4, are provided. Each of the shutter mechanisms 2 provided in FIGS. 7A-7B are the same as the shutter mechanism 2 of FIGS. 4A-4G, including the ability for each of the shutter mechanisms to cycle through the compound motion to open and close the shutter 20 as described herein. Each of the shutter mechanisms 2 of FIGS. 7A-7B are secured in close proximity to each other by a mounting plate 40, whereby the mounting tube 30 of each of the shutter mechanisms 2 are inserted and secured into a hole in the mounting plate 40. Each of the shutter mechanisms 2 may independently be able to cycle through the compound motion described herein. The deposition source 4 may be a sputter source. Each sputter source 4 may have a source material 6. Each source material 6 for each of the shutter mechanisms 2 may be the source material 6 for each shutter mechanism 2.

Alternatively, each source material 6 may be a different material for each of the shutter mechanisms 2. For example, at least one of the source materials 6 of the shutter mechanisms 2 may be different from the source materials 6 of the other shutter mechanisms 2, such as half of the source materials 6 of the shutter mechanisms 2 being of one source material and the other half of the source materials 6 of the shutter mechanisms 2 being of a different source material, such as each source material 6 of the shutter mechanisms 2 being different from each of the other source materials 6 of the plurality of shutter mechanisms 2. The arrangement of the plurality of shutter mechanisms 2 shown in FIGS. 7A-7B has the advantage of allowing the shutter mechanisms 2 with the same source material 6 to be in a first (open) position 50, while the shutter mechanisms 2 with different source materials 6 from the first group would be in third (closed) position 54, such that the different source material 6 from the second group may not contaminate the source materials 6 of the first group of the shutter mechanisms 2 that are open. Then, when the source material 6 to be deposited is to be changed, the first group of shutter mechanisms 2 may go through a compound motion to close, and the second group of shutter mechanisms 2 may go through a compound motion to open, such as to allow the second source material 6 to be deposited and the first source material 6 is now enclosed so that it does not contaminate the second source material 6.

With reference to FIG. 8, a shutter mechanism 2 with a deposition source 42 is provided. The shutter mechanism 2 may be similar to the shutter mechanism 2 FIGS. 1A-1D, including all the same components and optionally a smaller or larger size of one or more components. For example, the shutter mechanism 2 may be the same as the shutter mechanism of FIGS. 1A-1D. The shutter mechanism 2 includes the ability to move from a first (open) position 50 to a third (closed) position 54 using the compound motion detailed herein. The deposition source 42 may be a thermal evaporation source. A thermal evaporation source 42 is used in a PVD method that uses a resistive heat source to evaporate a source material 6 that is secured between two power feedthroughs 46, allowing the evaporated source material 6 to be deposited on a substrate. The shutter mechanism 2 and the thermal evaporation source 42 may be secured together with a mounting plate 44. The mounting plate 44 may also allow for the shutter mechanism 2 and the depositions source 42 to be secured to a different apparatus. Additionally, it is possible to secure additional shutter mechanisms 2 and deposition sources 42 to the mounting plate 44, as shown in FIG. 8. Therefore, it is possible to have a plurality of shutter mechanisms 2, each with a thermal evaporation source 42, on a mounting plate 44.

While several aspects of the present disclosure invention are shown in the accompanying figures and described in detail hereinabove, other aspects will be apparent to, and readily made by, those skilled in the art without departing from the scope and spirit of the disclosure. Accordingly the foregoing description is intended to be illustrative rather than restrictive. The invention described hereinabove is defined by the appended claims and all changes to the invention that fall within the meaning and range of equivalency of the claims are to be embraced within their scope.

The invention claimed is:

1. A shutter mechanism for a deposition source, comprising:
an actuator;
a shutter operatively connected to the actuator; and
a linkage arrangement that operatively connects the shutter to the actuator, wherein the linkage arrangement is configured to move the shutter in a compound motion relative to the actuator between an open position and a closed position.

2. The shutter mechanism of claim 1, wherein the compound motion comprises a linear movement of the shutter and a rotational movement of the shutter relative to the actuator, wherein the rotational movement moves the shutter between the open position and an intermediate position, and wherein the linear movement moves the shutter between the intermediate position and the closed position.

3. The shutter mechanism of claim 1, wherein the actuator is a mechanical actuator.

4. The shutter mechanism of claim 1, wherein, when in the open position, the shutter is located at an angle in the range of 40° to 90° relative to a positive y-axis that extends through the actuator.

5. The shutter mechanism of claim 1, wherein, when in the closed position, the shutter encloses at least one end of the deposition source.

6. The shutter mechanism of claim 1, wherein the linkage arrangement comprises at least one pin-in-slot joint that guides the shutter through the compound motion.

7. The shutter mechanism of claim 1, wherein the compound motion comprises only two types of movement for the shutter.

8. The shutter mechanism of claim 1, wherein the shutter comprises an overhang on an outermost rim of the shutter that is positioned around a source material when the shutter is held in the closed position.

9. The shutter mechanism of claim 1, wherein the deposition source is selected from the group consisting of a sputtering source, a low temperature evaporation source, an electron beam evaporation source, and a thermal evaporation source.

10. A shutter mechanism arrangement, comprising:
a plurality of deposition sources; and
a plurality of shutter mechanisms, wherein a single shutter mechanism is operatively connected to a single deposition source,
wherein each shutter mechanism comprises:
an actuator;
a shutter operatively connected to the actuator; and
a linkage arrangement that operatively connects the shutter to the actuator, wherein the linkage arrangement is configured to move the shutter in a compound motion relative to the actuator between an open position and a closed position.

11. The shutter mechanism arrangement of claim 10, wherein the compound motion comprises a linear movement of the shutter and a rotational movement of the shutter relative to the actuator, wherein the rotational movement moves the shutter between the open position and an intermediate position, wherein the linear movement moves the shutter between the intermediate position and the closed position.

12. The shutter mechanism arrangement of claim 10, wherein the actuator is a mechanical actuator.

13. The shutter mechanism arrangement of claim 10, wherein, when in the open position, the shutter is located at an angle in the range of 40° to 90° relative to a positive y-axis that extends through the actuator.

14. The shutter mechanism arrangement of claim 10, wherein, when in the closed position, the shutter encloses at least one end of the deposition source.

15. The shutter mechanism arrangement of claim 10, wherein the linkage arrangement comprises at least one pin-in-slot joint that guides the shutter through the compound motion.

16. The shutter mechanism arrangement of claim 10, wherein the compound motion comprises only two types of movement for the shutter.

17. The shutter mechanism arrangement of claim 10, wherein the shutter comprises an overhang on an outermost rim of the shutter that is positioned around a source material when the shutter is held in the closed position.

18. The shutter mechanism arrangement of claim 10, wherein the plurality of deposition sources are selected from the group consisting of a sputtering source, a low temperature evaporation source, an electron beam evaporation source, and a thermal evaporation source.

19. A method of enclosing a deposition source with a shutter mechanism, comprising the steps of:
actuating an actuator;
rotationally moving a shutter from an open position to an intermediate position; and
linearly moving the shutter from the intermediate position to a closed position in which the shutter encloses at least one end of the deposition source.

20. The method of claim 19, wherein the rotationally moving step comprises rotationally moving the shutter from an angle in the range of 40° to 90° relative to a positive y-axis of the actuator to an angle of about 0° relative to the positive y-axis.
